(19) United States
(12) Patent Application Publication
(10) Pub. No.: US 2003/0138991 A1
(43) Pub. Date: Jul. 24, 2003

(54) Method for forming a metal layer on an IC package

(76) Inventor: Moriss Kung, Taipei (TW)

Correspondence Address: Raymond Sun, 12420 Woodhall Way, Tustin, CA, 92782, US

(21) Appl. No.: 10/151,435

(22) Filed: May 20, 2002

(30) Foreign Application Priority Data
Jan. 22, 2002 (TW) 91100913

(51) Int. Cl. H01L 21/44; H01L 21/48

(52) U.S. Cl. 438/106

(57) ABSTRACT

The present invention is a method for forming a metal layer on an IC package which is applied to an IC package comprising a substrate and at least one chip on the substrate; the chip couples with the substrate via wire-bonding, flip-chip, etc.; further, an encapsulation covers at least on the chip and around the chip on the substrate; a metal-spraying layer is formed on partial non-conducting area of the IC package; a protective film can be optionally coated on the metal-spraying layer for protecting the metal-spraying layer; a thickness of the metal-spraying layer is decided depending on needs and easily changed to reach heat-dissipating and EMI shielding functions.

### 1. FIELD OF THE INVENTION

The present invention is a method for forming a metal layer on an IC package, especially applied on that to coat a metal layer on an IC package via spraying, and based on practicability to adjust spraying parameters to determine a thickness of the metal layer.

### 2. BACKGROUND OF THE INVENTION

As electrical engineering being improved continuously, electrical system and electrical package are designed to occupy spaces as small as possible, therefore a space to load IC is very precious, and the space should be used as possible as we can. To approach above object, reducing IC is an effective way to use space, and the reduced IC accelerates calculating speed, lessens interference and other strong points. However, heat-dissipating problem is appeared after IC reduced, especially heat generated by increasing components and transistors on a single semiconductor component.

One of the formations of semiconductor chip package includes a substrate connected by one or multiple chips. Usually the package connects to a printed circuit board (PCB) or a printed circuit card. There are plural methods for chips connecting to a substrate, and wire-bonding is the most way. The wire-bonding adopts a tiny wire to electrically connect chip and substrate. Another way is flip-chip, which takes solder bump to practically touch and electrically connect chip and substrate. To approach heat-dissipating purpose for normal chip operation, usually adding heat-dissipating flanges made of introducing heat material to exhaust heat.

Please refer FIG. 1A to FIG. 1C, which are process schemes of an IC package of a prior wire-bonding. An IC package 1, which is a package formation and comprises a substrate 11 and a chip 13 on the substrate 11. Upper and lower sides of substrate 11 are distributed plural printed circuit layers (not shown in figures); further, substrate 11 can be a single or multiple layers. Chip 13 couples to substrate 14 via wire-bonding. An encapsulation 15 is distributed on and around chip 13, and a main purpose is to cover the IC package 1. Finally, IC package 1 is connected to a printed circuit board via plural solder bumps.

A heat-dissipating flange 17 is a metal piece made of heat-dissipating material as copper and formed to fit with a figure of IC package 1 via punch, press and molding, which is shown in FIG. 1B. For closely matching the heat-dissipating flange 17 with IC package 1, firstly coating two adhering layers 16a and 16b on the encapsulation 15 and partial area of substrate 11, then pressing heat-dissipating flange 17 on IC package 1 for dissipating heat.

Referring to FIG. 2A to FIG. 2C, which are process schemes of a flip-chip IC package. As mentioned above, an IC package 2 mainly comprises a substrate 21 and a chip 23 on the substrate 21, the difference with mentioned above is the chip 23 couples to the substrate 21 via the flip-chip method of plural solder bumps 24 to conduct electricity. Finally, IC package 2 is connected to a printed circuit board via plural solder balls 22.

A heat-dissipating flange 27 is a metal piece made of heat-dissipating material as copper and formed to fit with a figure of IC package 2 via punch, press and molding, which is shown in FIG. 2B. For closely matching the heat-dissipating flange 27 with IC package 2, firstly coating two adhering layers 26a and 26b on the chip 23 and partial area of substrate 21, then pressing heat-dissipating flange 27 on IC package 2 for dissipating heat shown as FIG. 2C.

However, the above heat-dissipating flange has following shortcomings:

(1) The heat-dissipating flange is firstly formed to fit with the shape of the IC package via punch, press and molding, and they should be completely matched each other; hence, we would know a whole process is complicate and needs higher cost.

(2) Equipment for the process is expensive, thus some of the cost is wasted.

(3) The heat-dissipating flange may hardly be made if the shape of IC package is confuse, and application range is seriously limited and easily happened mistake.

(4) Another complicate equipment executes the press procedure when a heat-dissipating flange matching with IC package.

(5) Manufacturing amount is low, so mass-production is hardly made.

We would know the process of the heat-dissipating flange of the IC package still has the space to be improved, and the business also expects the most effective operation can be reached via some improvement.

Based on the aforesaid issues, the present inventor of the patent has being studied and referred to practical experiences and theory for designing and effectively improving the prior arts.

### SUMMARY OF THE INVENTION

The first object is to provide a method for forming a metal layer on an IC package, especially applied on that to coat a metal layer on an IC package via spraying, and based on practicability to adjust spraying parameters to determine a thickness of the metal layer.

The second object is to provide a method for forming a metal layer on an IC package, a metal-spraying frame is added to reach heat-dissipating and electromagnet-shielding functions, and the metal-spraying frame can be formed at any formation and dimension, complicate equipment is no longer needed; further, the metal-spraying frame is easily to be in mass-production.

The third object is to provide a metal-spray method for forming a metal layer on an IC package, the metal-spray method is to coat a metal layer on a wafer including plural chips, therefore the metal layer on chips of the IC package can be a role of heat-dissipation.

To reach above objects, a method for forming a metal layer on an IC package of the present invention gets rid of prior surface metal of IC package formed by punch, press or molding and adopts a metal-spraying method to produce a metal-spraying layer. An IC package of the present invention comprises a substrate and at least one chip on the substrate; the chip couples with the substrate via wire-bonding or flip-chip to be packaged. The metal-spraying method is applied on non-conducting area of IC package to become a metal-spraying layer consisted of pure metal or alloy. The metal-spraying is an arc melting spray, and a thickness of the metal-spraying layer is able to be adjusted very easily, thus the heat-dissipating and anti-electromagnet function are approached for keeping normal operation of the IC.

Preferably, the present invention also applies the metal-spraying method on the process of producing IC package. A back of a wafer with plural accomplished chips is coated a metal layer via the metal-spraying method, then the wafer can be taken apart to become many single chips. Each single chip is processed by packaged procedures to let the chip with metal layer on its back be mounted on a substrate, then an IC package is completed. Further, because the chip is coated the metal layer, thus the IC package has the metal layer as well, and the metal layer is the present role of heat-dissipation for keeping normal operation of those chips.

The appended drawings will provide further illustration of the present invention, together with description; serve to explain the principles of the invention.

### BRIEF DESCRIPTION OF THE DRAWINGS

FIGS. 1A to 1C are process schemes of an IC package of a prior wire-bonding.

FIGS. 2A to 2C are process schemes of an IC package of a prior flip-chip.

FIGS. 3A to 3B are process schemes of a first embodiment of a metal-spraying layer of the present invention.

FIGS. 4A to 4C are process schemes of a second embodiment of a metal-spraying surface of the present invention.

FIGS. 5A to 5G are process schemes of a third embodiment of a metal-spraying frame of the present invention.

FIGS. 6A to 6D are process schemes of a fourth embodiment of a metal-spraying method of the present invention.

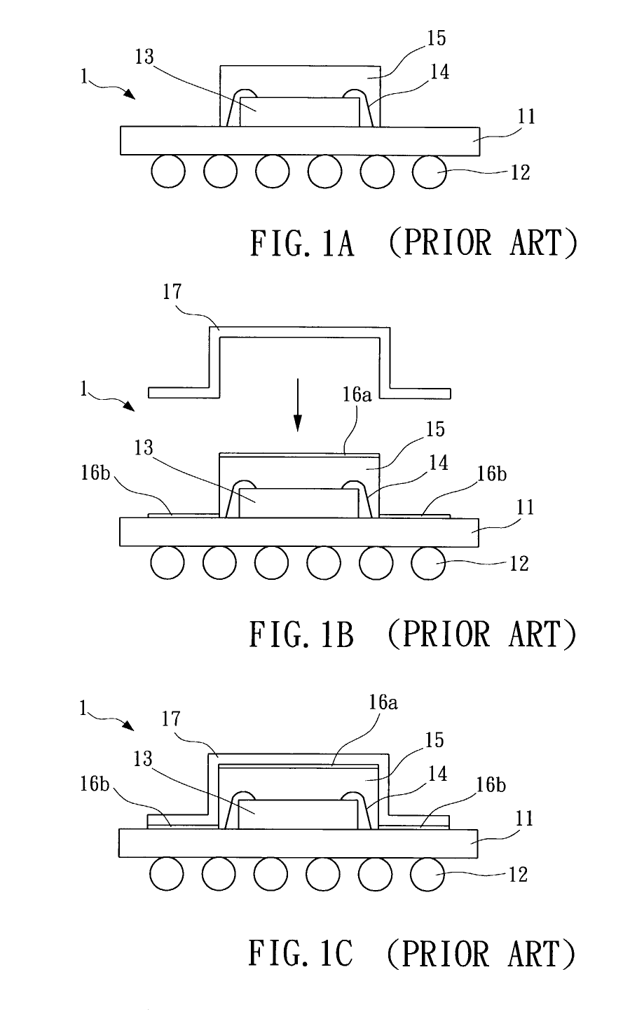

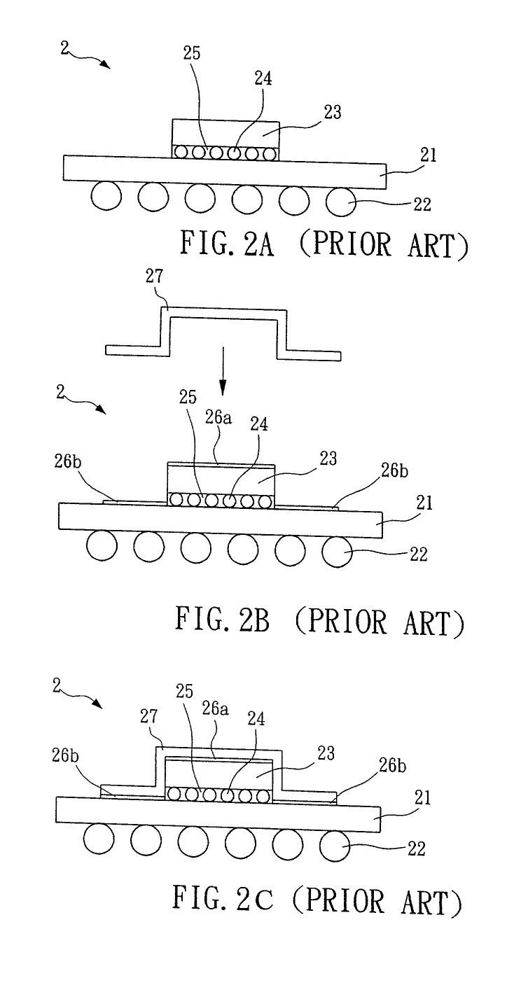

### DETAILED DESCRIPTION OF THE PRESENT INVENTION

One of the main features is to get rid of punch, press or molding and adopt a metal-spraying method to produce a metal-spraying layer. Manufacturing process and application of the present invention are both easy and wide to fit with almost any dimension of IC package. Besides, the sprayed area could have ground opening pads exposed on the substrate or IC for ground connecting to the overall sprayed profile.

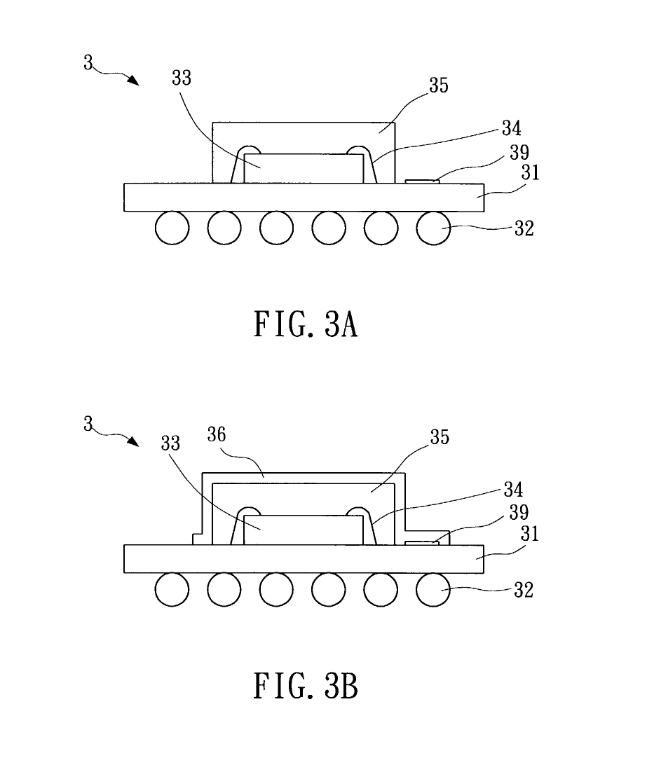

Please refer to FIGS. 3A to 3B, which are process schemes of a first embodiment of a metal-spraying layer of the present invention. An IC package 3 is a general package embodiment of the business, and it comprises a substrate 31 and a chip 33 on the substrate 31, and normally the chip number can be installed at least one or more, the figures only shows one piece of chip. Substrate 31 is made of ceramic or plastic, ceramic substrate has an insulating layer with ceramic material, plastic substrate has an insulating layer with plastic material, which including bismaleimide (BMI), bismaleimide triazine-based (BT), epoxy FR-4 or polyamide, etc. Upper and lower sides are distributed plural printed circuit board (not shown in figures) on substrate 31, and substrate 31 may be consisted of a single layer or multiple layers. Chip 33 couples with substrate 31 via wire-bonding. An encapsulation 35 is at least coated on chip 33 and around chip 33 on substrate 31 to protect packaged BGA components and chip 33. There is a ground pad 39 on substrate 31, and the ground pad is located on where the encapsulation 35 does not cover. The IC package 3 is connected to the printed circuit board by plural solder balls 32.

Following is one of the focus of the present invention, which is as shown in FIG. 3B and to get rid of punch, press or molding and adopt a metal-spraying method to apply on non-conducting area of IC package to become a metal-spraying layer 36 consisted of pure metal or alloy, pure metal is as copper, aluminum, zinc, etc. The metal-spraying layer 36 covers the ground pad 39 on substrate 31, therefore a contact area is enlarged to result promotion of the IC package 3 efficiency as shown in FIG. 3B.

The metal-spraying method is an arc melting spray, and the arc melting spray of the preferred embodiment is PEC PC-300 arc melting spray; wherein sprayed particles are within a range of dimensions of 1 μm to 10 μm, a preferred range is between 4 μm to 6 μm; a range of adhering forces of the particles is between 100 kg/cm² to 300 kg/cm², a preferred range is of 160 kg/cm² to 281 kg/cm², such as 160 kg/cm² of aluminum and 281 kg/cm² of zinc, or Gold, Silver, Tin, Tin/Lead alloy, other alloy etc.; a method for delivering wire material is a push/pull method, a diameter range of the wire is between 1.0 to 3.0 mm, a preferred range is between 1.6 to 2.4 mm; in a room temperature, a temperature range of the tip of the arc melting spray head is from 4000 to 6000° C.; sprayed particles are cooled down instantly and then coats on a coated object. The above operation can be processed in the room temperature. Further, a thickness of a metal-spraying layer 46 is easily changed to reach better heat-dissipating effect and EMI result, therefore an IC chip 33 can operate normally.

Before engaging in metal-spraying, a protect film (ex. resin) can be coated on partial non-conducting area of IC package 3.

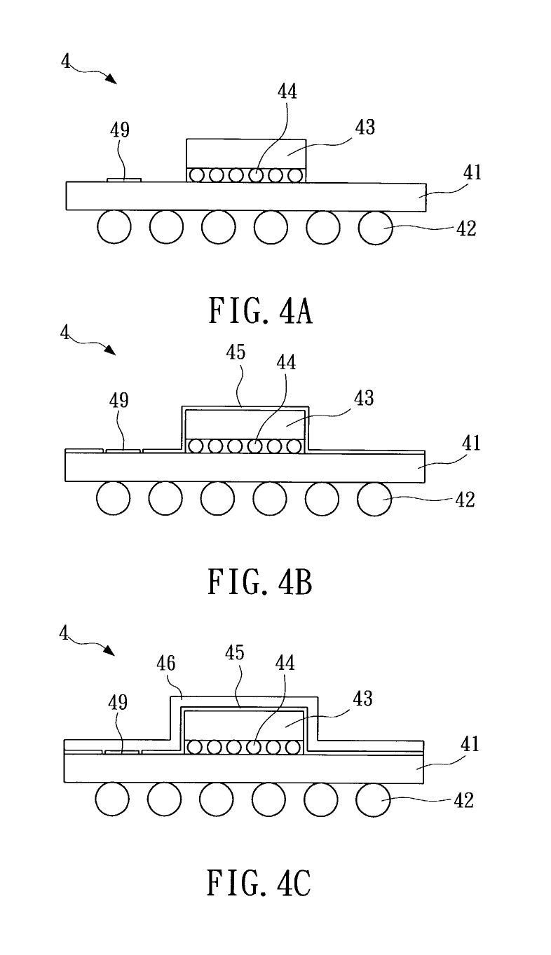

The present invention is able to apply a flip-chip method on IC package, such as shown from FIGS. 4A to 4C. Following is the second embodiment of the present invention. Same as the previous embodiment, an IC package 4 comprises a substrate 41 and a chip 43 on the substrate 41. There is only one chip 43 shown on the figures. The substrate 41 can be made of plastic or ceramic material, and the design and the material of substrate 41 are same as the first embodiment. The difference of the second embodiment and the first embodiment is that a solder bump 44 couples with substrate 41 via flip-chip method, then putting an encapsulation on it for protection (not marked in figures). As the previous embodiment, there is a ground pad 49 on substrate 41 for ground connection.

A protect film 45 (ex. resin) can be coated on partial non-conducting area of IC package 4, but a notice is the protection film 45 shall be avoided a location of the ground pad 49, another words, protection film 45 does not shield ground pad 49.

As aforesaid embodiment, to directly spray a metal-spraying layer 46 on partial non-conducting area (protection film 45), and the metal-spraying layer 46 consists of a pure metal as cooper, aluminum, zinc, etc. Ground pad 49 on substrate 41 is shielded by metal-spraying layer 46, this causes that enlarging contact area and promoting IC package 4 efficiency, shown as FIG. 4C.

The metal-spraying method is an arc melting spray, and the arc melting spray of the preferred embodiment is PEC PC-300 arc melting spray; wherein particles sprayed are within a range of dimensions of 1 μm to 10 μm, a preferred range is between 4 μm to 6 μm; a range of adhering forces of the particles is between 100 kg/cm² to 300 kg/cm², a preferred range is of 160 kg/cm² to 281 kg/cm², such as 160 kg/cm² of aluminum and 281 kg/cm² of zinc; a method for delivering wire material is a push/pull method, a diameter range of the wire is between 1.0 to 3.0 mm, a preferred range is between 1.6 to 2.4 mm; in a room temperature, a temperature range of the tip of the arc melting spray head is from 4000 to 6000° C.; sprayed particles are cooled down instantly and then coats on a coated object. The above operation can be processed in the room temperature. Further, a thickness of a metal-spraying layer 46 is easily changed to reach better heat-dissipating effect and EMI result, therefore an IC chip 43 can operate normally.

However, the IC package 3 does not only comprises the metal-spraying layer 46 of the present invention, but also other electric resistance, electric capacity, IC components, etc. (not shown in figure), and above mention belongs to prior art, further, it is not a feature of the present invention as well, so no more discussion for that.

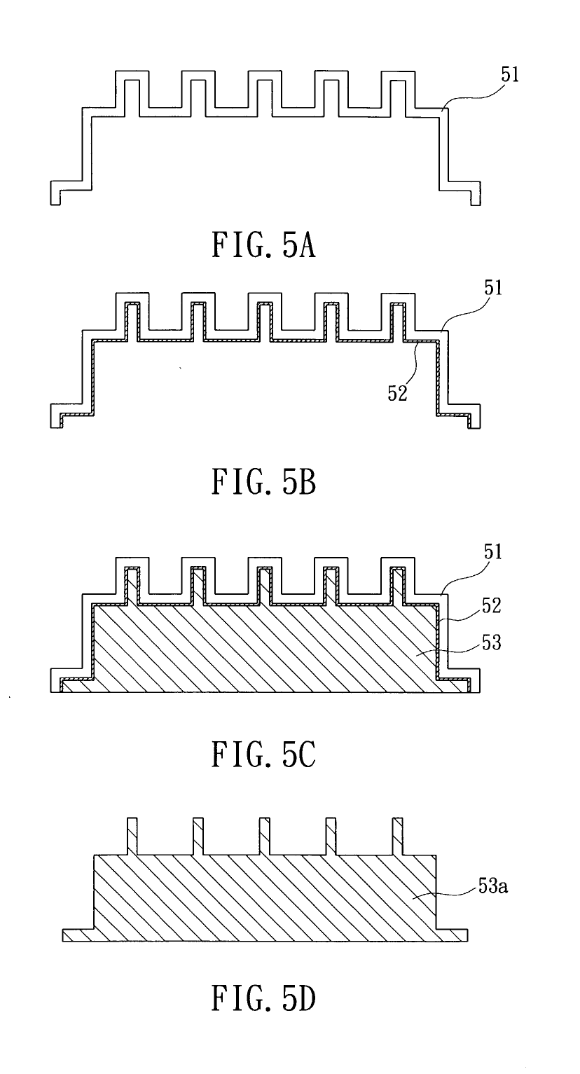

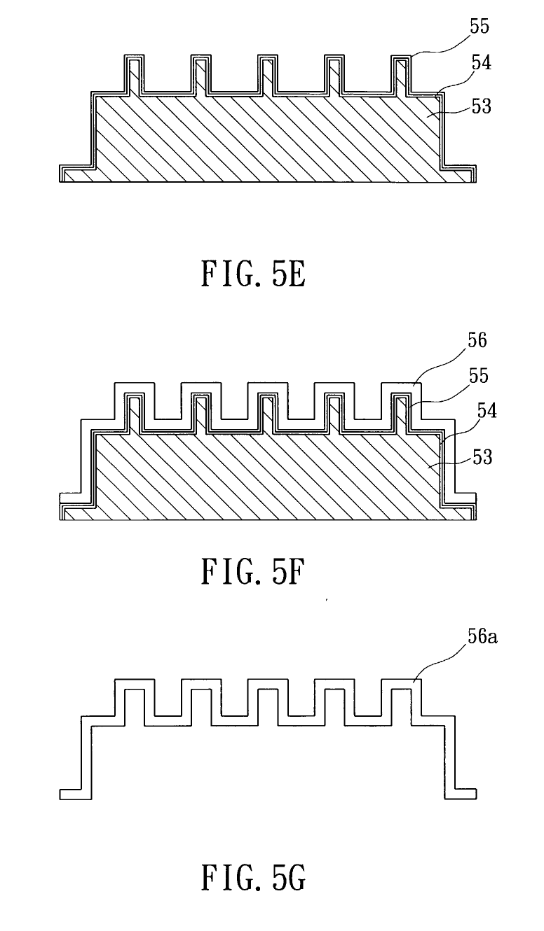

Except the method for coating an IC package, other different figures and thicknesses of heat-dissipating flanges and EMI shielding can be made to apply to plural types of IC packages. Referring to FIGS. 5A to 5G, which are process schemes of a third embodiment of a metal-spraying frame of the present invention, which comprises procedures:

(a) Offering a metal-spraying frame 51, which includes a cavity, and the metal-spraying frame 51 can be made by general technology;

(b)Coating a release film 52 on the inner surface of the cavity of metal-spraying frame 51 via spraying, the release film 52 is made of epoxy resin, etc.;

(c) Coating a metal layer 53 on release film 52 via spraying to fulfill cavity;

(d)Removing metal-spraying frame 51 to make the metal layer 53 becomes a metal-spraying mold 53a, and the metal-spraying mold 53a is a main mold for producing a metal-spraying frame.

(e) Coating a release agent 54 and a release film 55 on metal-spraying mold 53a in sequence via spraying, such as epoxy resin, etc.;

(f) Coating a metal-spraying layer 56 on the release film 55 via spraying, metal material is as copper, aluminum, zinc or other alloy;

(g)Removing metal-spraying mold 53a to make the metal-spraying layer 56 forms a metal-spraying frame 56a.

Above mentioned spraying methods are arc melting spray or other high speed metal-spraying technologies. Sprayed particles which dimensions are between 1 μm to 10 μm, adhering forces of particles are between 100 kg/cm² to 300 kg/cm², the temperature range of the top end of the arc melting spray head is from 4000 to 6000° C.; those sprayed particles are cooled down and coats on the coated object, above operations can be made under a room temperature circumstance.

Metal-spraying frame 56a produced by the present invention can be applied to different IC packages. When individually producing many different thicknesses and figures of metal-spraying frames 56a with heat-dissipating and EMI shielding functions, firstly following procedures (a) to (d) to make metal-spraying mold 53a, and metal-spraying mold 53a can be a main mold to repeat procedures (e) to (g) for producing plural metal-spraying frames 56a. Then, combining those IC packages via an adhering method, for instance, applying to package methods of a plastic pin grid array (PPGA), a plastic ball grid array (PBGA) and a plastic column grid array (PCGA), or molding substrates with special needs for reaching heat-dissipating and EMI shielding functions.

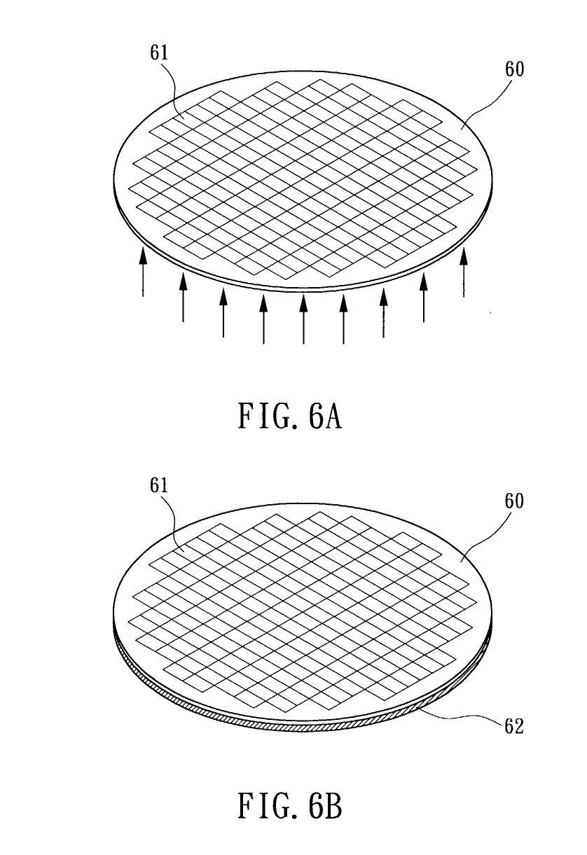

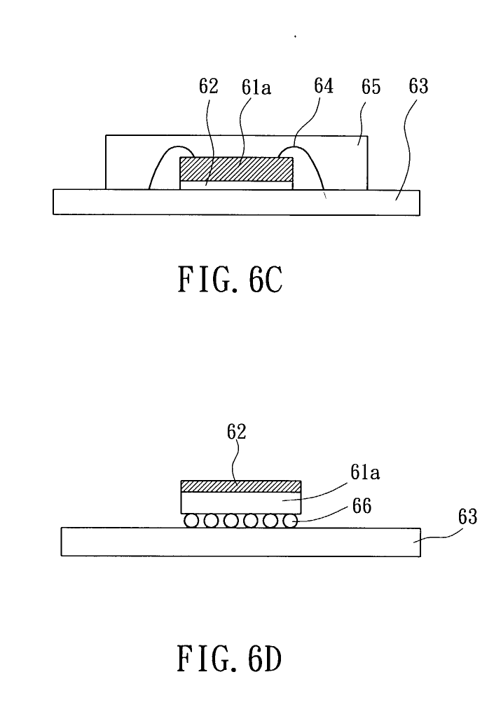

On the other hand, the spirits of the present invention is the following embodiment. Referring to FIGS. 6A to 6C, which are process schemes of a fourth embodiment of a metal-spraying method of the present invention, the procedures comprise:

(a) To offer a wafer 60, which includes plural accomplished chips 61. Each chip 61 is able to independently operation and a normal IC chip. The manufacturing process skill for chip 61 is known already and not the focus of the present invention, so it is not discussed here any further.

(b) As aforesaid metal-spraying method, there is a metal layer 62 on a back of wafer 60.

(c) As general mechanical cutting method to cut wafer 60 apart, then plural combined chips 61 are divided to single chips 61a, continuously a package process is engaged in the single chip 61a to coat the metal layer 62 on a back of chip 61a, further, chip 61a is mounted on a substrate 63, and an IC package is constructed. Chip 61a adopts a wire 64 to couple with substrate 63 via wire-bonding method. Encapsulation 65 shields chip 61a and an area around substrate 63 at least.

(d) The metal-spraying method can be applied to a flip-chip IC package, shown as FIG. 6D. Chip 61a with metal layer 62 is coupled with substrate 63 by a solder bump 66 via flip-chip.

It depends on the needs that the present embodiment can add more than one chip, and there is only one chip 61a shown in figures. The design, material of substrate 63 are same as above embodiment, so no more discussion here. A back of wafer 60 with plural accomplished chips 61 is coated metal layer 62 via the metal-spraying method, then wafer 60 can be taken apart to become many single chips 61. Each single chip 61 is processed by packaged procedures to let chip 61 with metal layer 62 on its back be mounted on substrate 63, further, because the chip back is coated metal layer 62, thus the IC package has metal layer 62 as well, and metal layer 62 is the present role of heat-dissipation for keeping normal operation of those chips 61.

Metal layer 62 is consisted by pure metal, such as copper, aluminum, zinc, or other alloys, etc. The metal-spraying method is an arc melting spray, and the arc melting spray of the preferred embodiment is PEC PC-300 arc melting spray; wherein particles sprayed are within a range of dimensions of 1 μm to 10 μm, a preferred range is between 4 μm to 6 μm; a range of adhering forces of the particles is between 100 kg/cm² to 300 kg/cm², a preferred range is of 160 kg/cm² to 281 kg/cm², such as 160 kg/cm² of aluminum and 281 kg/cm² of zinc; a method for delivering wire material is a push/pull method, a diameter range of the wire is between 1.0 to 3.0 mm, a preferred range is between 1.6 to 2.4 mm; in a room temperature, a temperature range of the tip of the arc melting spray head is from 4000 to 6000° C.; sprayed particles are cooled down instantly and then coats on a coated object. The above operation can be processed in the room temperature. Further, a thickness of metal-spraying layer 62 is easily changed to reach better heat-dissipating effect.

To conclude above mentions, there are plural advantages of the present invention comparing to prior arts, which are listed as following:

(1) The present invention is to coat a metal layer on an IC package via spraying, and it can be applied to plural packages with different formations and dimensions.

(2) The metal layer coated on IC package has heat-dissipating and EMI shielding functions. Furthermore, through the exposed ground pads on substrate or IC, the sprayed metal could connect to the overall sprayed profile to promote better electrical property.

(3) The thickness of the metal layer coated on IC package is decided depending on practical needs to alter parameters of a metal spraying process.

(4) The present invention can be applied to ceramic substrate and plastic substrate, further, wafer and glass substrate are other options as well.

(5) The present invention has features of high producing quantity and simple process; therefore mass-production can be easily made.

(6) The metal-spraying frame can be made as any formation and dimensions.

(7) The process can be applied in a room temperature.

(8) To directly spray metal on a back of a wafer for forming a metal layer with heat-dissipation function, the heat-dissipation uniformity is excellent, and the processing of the metal layer is easier.

While the present invention has been shown and described with reference to preferred embodiments thereof, and in terms of the illustrative drawings, it should be not considered as limited thereby. Thus, the present invention is infinitely used. However, various possible modification, omission, and alterations could be conceived of by one skilled in the art to the form and the content of any particular embodiment, without departing from the scope and the sprit of the present invention.

The invention is disclosed and is intended to be limited only the scope of the appended claims and its equivalent area.

What is claimed is:

1. A method for forming a metal layer on an IC package, which procedures including:
(a) Supplying an IC package, which comprising at least one substrate and at least one chip on the substrate; and
(b) Forming a metal-spraying layer on a partial surface of the IC package via a metal-spraying method.

2. The method for forming a metal layer on an IC package as cited in claim 1, wherein a procedure (b′) before the procedure (b) can be further included, and the procedure (b′) is to form a protective film on a partial surface of IC package via spraying.

3. The method for forming a metal layer on an IC package as cited in claim 1, wherein the metal-spraying layer is formed on a non-conducting area of the IC package.

4. The method for forming a metal layer on an IC package as cited in claim 1, wherein the metal-spraying method is arc melting spray.

5. The process for forming a metal layer on an IC package as cited in claim 4, wherein dimensions of sprayed particles of the arc melting spray are between 1 μm to 10 μm.

6. The process for forming a metal layer on an IC package as cited in claim 4, wherein adhering forces of sprayed particles of the arc melting spray are between 100 kg/cm² to 300 kg/cm².

7. The process for forming a metal layer on an IC package as cited in claim 4, wherein temperatures of the tip of the arc melting spray head is from 4000 to 6000° C.

8. The method for coating an IC device as cited in claim 1, wherein the substrate further has a ground pad.

9. A process for forming a metal frame on an IC package, which procedures including:
(a) Supplying a mold;
(b) Forming a first release film on the mold via a spray method;
(c) Forming a first metal-layer on the release film via a spray method; and
(d) Removing the mold to form a metal frame from the first metal-spraying layer.

10. The process for forming a metal frame on an IC package as cited in claim 9, wherein the mold of procedure (a) is produced by following procedures:
(a1) Supplying a frame, which has a cavity;
(a2) Forming a second release film on the inner surface of the cavity of the frame via a spray method;
(a3) Forming a second metal layer on the release film via a spray method to fulfill the cavity; and
(a4) Removing the frame to form the mode from the second metal layer.

11. The process for forming a metal frame on an IC package as cited in claim 10, wherein a procedure (a2′) before the procedure (a2) can be included, and the procedure (a2′) is to form a release agent on the mold via a spray method.

12. The process for forming a metal frame on an IC package as cited in claim 9, wherein the spray method of the procedure (c) is arc melting spray.

13. The process for forming a metal frame on an IC package as cited in claim 12, wherein dimensions of sprayed particles of the arc melting spray are between 1 μm to 10 μm.

14. The method for forming a metal frame on an IC package as cited in claim 12, wherein adhering forces of sprayed particles of the arc melting spray are between 100 kg/cm² to 300 kg/cm².

15. The method for forming a metal frame on an IC package as cited in claim 12, wherein temperatures of the tip of the arc melting spray head is from 4000 to 6000° C.

16. A method for forming an IC package, which procedures comprising:
(a) Providing a wafer having a plurality of accomplished chips;
(b) Coating a metal layer on the backside of the wafer via a metal-spray method; and
(c) Cutting the wafer apart to produce a plurality of single chips; and
(d) Mounting each single chip on a substrate to engage in an IC package process.

17. The method for forming an IC package as cited in claim 16, wherein the metal-spraying method is arc melting spray.

18. The method for forming an IC package as cited in claim 17, wherein dimensions of sprayed particles of the arc melting spray are between 1 μm to 10 μm.

19. The method for forming an IC package as cited in claim 17, wherein adhering forces of sprayed particles of the arc melting spray are between 100 kg/cm² to 300 kg/cm².

20. The method for forming an IC package as cited in claim 17, wherein temperatures of the tip of the arc melting spray head is from 4000 to 6000° C.
